(19) United States
(12) Patent Application Publication
(10) Pub. No.: US 2014/0154891 A1
(43) Pub. Date: Jun. 5, 2014

(54) Beam Delivery Systems for Laser Processing Materials and Associated Methods

(71) Applicant: SiOnyx, Inc., Beverly, MA (US)

(72) Inventors: Keith Donaldson, Beverly, MA (US); Jason Sickler, Arlington, MA (US); James E. Carey, Waltham, MA (US); Romek Nowak, Cupertino, CA (US)

(21) Appl. No.: 13/931,624

(22) Filed: Jun. 28, 2013

Related U.S. Application Data
(60) Provisional application No. 61/692,136, filed on Aug. 22, 2012.

(51) Int. Cl. H01L 21/324; H01L 21/67; G21K 5/08

(52) U.S. Cl. CPC H01L 21/324; G21K 5/08; H01L 21/67115
USPC 438/795; 250/492.2

(57) ABSTRACT

Devices, systems, and methods for laser processing semiconductor materials are provided. In one aspect, a system for uniformly laser irradiating at least one wafer can include a wafer platter operable to receive and support a one or more wafers, a rotational movement system coupled to the wafer platter, the rotational movement system being operable to rotate the wafer platter in at least one of a clockwise or a counter clockwise direction, and a linear movement system coupled to the wafer platter and operable to move the wafer platter along one or more linear axes. The system can also include a laser source oriented to deliver laser radiation onto a wafer supported by the wafer platter at a fixed angle relative to the surface of the wafer, where the rotational movement system and the linear movement system are operable to maintain the fixed angle across the entirety of the wafer surface.

### PRIORITY DATA

This application claims the benefit of U.S. Provisional Patent Application Ser. No. 61/692,136, filed on Aug. 22, 2012, which is incorporated herein by reference.

### BACKGROUND

Short-pulse laser radiation can be used to treat a variety of semiconductor materials in order to enhance their functionality. For example, the properties of silicon photodetectors can be improved using short pulse laser radiation treatment. Many traditional techniques for semiconductor surface modification, including doping, using short-pulse laser radiation, etc., typically involve placing a single semiconductor wafer in a sealed chamber, vacuum evacuating the chamber, filling the chamber with doping or inert fluids, laser irradiating the wafer, evacuating the chamber of the fluids, and opening the chamber to remove the wafer.

### SUMMARY

Devices, systems, and methods for laser processing semiconductor materials are provided. In one aspect, for example, a system for uniformly laser irradiating at least one wafer can include a wafer platter operable to receive and support a one or more wafers, a rotational movement system coupled to the wafer platter, the rotational movement system being operable to rotate the wafer platter in at least one of a clockwise or a counter clockwise direction, and a linear movement system coupled to the wafer platter and operable to move the wafer platter along one or more linear axes. The system can also include a laser source oriented to deliver laser radiation onto a wafer supported by the wafer platter at a fixed angle relative to the surface of the wafer, where the rotational movement system and the linear movement system are operable to maintain the fixed angle across the entirety of the wafer surface. In another aspect, the linear movement system can be operable to move the wafer platter along at least two linear directions. In yet another aspect, the linear movement system can be operable to move the wafer platter along at least three linear directions. In a further aspect, the fixed angle can be substantially normal to the surface of the wafer. In yet a further aspect, the fixed angle can be within about ±15° of the Brewster's angle for the wafer material.

It is additionally contemplated that in some aspects the system can further include a housing configured to at least partially enclose the wafer platter. Furthermore, in another aspect the system can further include a fluid input system coupled to the housing and operable to deliver a fluid therein. In yet another aspect, the system can further include a fluid output system coupled to the housing and operable to remove a fluid therefrom. Such a fluid output system can also remove waste material and other debris therefrom. In yet another aspect, the system can include multiple wafer platters for processing multiple wafers.

Numerous types of lasers and laser configurations are contemplated, and as such the descriptions of lasers provided herein should not be seen as being limiting. In one aspect, however, the system can include multiple laser sources for processing one or more wafers. In another aspect, the laser source is a short pulse laser source having an output power of greater than 10 W. In yet another aspect, the laser source is a short pulse laser source having an output power of greater than 30 W. In a further aspect, the laser source is operable to emit short pulses having a duration of from about 10 femtoseconds to about 500 picoseconds.

In one aspect, a method of uniformly lasing at least one wafer is provided. Such a method can include applying short-pulse laser radiation to a wafer disposed on a wafer platter from a laser source, where the laser radiation is emitted at a fixed angle relative to the wafer surface, and performing a combination of rotating and linearly translating of the wafer to deliver the laser radiation to a target region of the wafer while maintaining the laser radiation at the fixed angle. The combination of rotating and translating is operable to provide a substantially identical fluence exposure history regardless of position over the entire target region of the wafer. In another aspect, the target region is substantially all of the wafer surface. In yet another aspect, the combination of rotating and translating can be operable to maintain a substantially identical fluence exposure history where the laser radiation contacts the wafer at an edge region of the wafer as compared to a center region of the wafer. In a further aspect, the fixed angle can be substantially normal to the surface of the wafer.

In another aspect, a method of uniformly lasing a plurality of wafers in a single batch process is provided. Such a method can include loading a plurality of wafers onto at least one wafer platter in a single housing, delivering short-pulse laser radiation to the plurality of wafers at a fixed angle relative to the surface of the wafer, and performing a combination of rotating and translating of each of the plurality of wafers to laser irradiate a target region on each of the plurality of wafers while maintaining the laser radiation at the fixed angle. The combination of rotating and translating is operable to maintain a substantially identical fluence exposure history across substantially the entire target region of each of the plurality of wafers to uniformly lase the target region. In one aspect, the fixed angle can be substantially normal to the surface of the wafer. In another aspect, the target region is substantially all of the wafer surface. In yet another aspect, delivering short-pulse laser radiation further includes delivering short-pulse laser radiation from a plurality of laser sources. In a further aspect, delivering short-pulse laser radiation from a plurality of laser sources further includes delivering short-pulse laser radiation to at least a portion of the plurality of wafers simultaneously. In yet a further aspect, the short-pulse laser radiation has a laser pulse duration of from about 10 femtoseconds to about 500 picoseconds.

### BRIEF DESCRIPTION OF THE DRAWINGS

For a fuller understanding of the nature and advantage of the present disclosure, reference is being made to the following detailed description of various embodiments and in connection with the accompanying drawings, in which:

FIG. 1 shows a side view of a laser processing system in accordance with one aspect of the present disclosure;

FIG. 2 shows a top-down view wafer being laser processed in accordance with another aspect of the present disclosure;

FIG. 3 shows a top-down view of the wafer platter having multiple wafers being laser processed in accordance with another aspect of the present disclosure;

FIG. 4 shows a graph representing data showing constant linear velocity scans across a 200 mm wafer in accordance with another aspect of the present disclosure;

FIG. 5 shows a schematic view of the laser processing system in accordance with another aspect of the present disclosure;

FIG. 6 shows a schematic view of the laser processing system in accordance with another aspect of the present disclosure;

FIG. 7 shows a flow diagram of a method of uniformly lasing at least one wafer in accordance with another aspect of the present disclosure; and

FIG. 8 shows a flow diagram of a method of uniformly lasing multiple wafers in accordance with another aspect of the present disclosure;

### DETAILED DESCRIPTION

Before the present disclosure is described herein, it is to be understood that this disclosure is not limited to the particular structures, process steps, or materials disclosed herein, but is extended to equivalents thereof as would be recognized by those ordinarily skilled in the relevant arts. It should also be understood that terminology employed herein is used for the purpose of describing particular embodiments only and is not intended to be limiting.

Definitions

The following terminology will be used in accordance with the definitions set forth below.

It should be noted that, as used in this specification and the appended claims, the singular forms “a,” and, “the” include plural referents unless the context clearly dictates otherwise. Thus, for example, reference to “a dopant” includes one or more of such dopants and reference to “the layer” includes reference to one or more of such layers.

As used herein, the term “fluence” refers to the amount of energy from a single pulse of laser radiation that passes through a unit area. In other words, “fluence” can be described as the energy density of one laser pulse.

As used herein, the term “fluence exposure history” refers to the series of fluences in time that a given portion of the wafer surface has experienced. In one aspect, for example, the portion of the wafer surface can be the beam area of the laser used to process the surface. Another aspect, the portion of the wafer surface can have an area of about a square micron or about a square millimeter.

As used herein, the term “actively” when used to describe the replenishing or replenishment of a fluid layer refers to intermittently or continuously adding dopants species or inert species to the fluid layer. It is noted that, for purposes of this disclosure, term “intermittently” can refer to either regular or sporadic additions of dopant species or inert species to the fluid layer. Whether continuous or intermittent, the active replenishment of the fluid layer does not include situations where a vacuum is released from a chamber containing a semiconductor material and a fluid is added, followed by reestablishment of a vacuum in the chamber. It is thus intended that active replenishment be accomplished at room pressure.

As used herein, the term “room pressure” refers to the pressure immediately outside of an enclosure in which the surface modification and/or doping is occurring. Thus the term, “room pressure” is intended to describe the situation where the pressure inside the enclosure is substantially the same as the pressure outside the enclosure. It is noted that the room pressure will vary with altitude, and it is intended that this term be relative to the altitude at which the method is performed. In some aspect, however, room pressure can be measured relative to atmospheric pressure. For example, in one aspect room pressure is within 15% of atmospheric pressure. In another aspect, room pressure is within about 10% of atmospheric pressure. In yet another aspect, room pressure is within about 5% of atmospheric pressure. It should also be noted that the term “atmospheric pressure” refers to the pressure of the atmosphere at sea level namely about 760 Torr.

As used herein, the term “fluid” refers to a continuous liquid or gas that tends to flow and to conform to an enclosing structure.

As used herein, the term “target region” refers to an area of a semiconductor material that is intended to be doped or surface modified using laser radiation. The target region of a semiconductor material can vary as the surface modifying process progresses. For example, after a first target region is laser processed or surface modified, a second target region may be selected on the same semiconductor material.

As used herein, the terms “surface modifying” and “surface modification”, refer to the altering of a surface of a semiconductor material using laser radiation. Surface modification can include processes using primarily laser radiation or laser radiation in combination with an inert fluid or a dopant fluid. The laser radiation can facilitate the incorporation of a dopant form the dopant fluid into a surface of the semiconductor material. Accordingly, in one embodiment surface modification includes doping of a semiconductor material.

As used herein, “adjacent” refers to being near or sufficiently close to achieve a desired effect. Although direct physical contact is most common and preferred in the layers of the present disclosure, adjacent can broadly allow for spaced apart features, provided the functionality of the methods described herein can be accomplished.

As used herein, the term “laser processing” refers to the modification of a region of a region of a semiconductor material using a short-pulsed laser to form a textured region or surface.

As used herein, the terms “surface modifying” and “surface modification” refer to the altering of a surface of a semiconductor material using a laser processing technique. In one specific aspect, surface modification can include processes using primarily laser radiation. In another aspect, surface modification can include processes using laser radiation in combination with a dopant, whereby the laser radiation facilitates the incorporation of the dopant into a surface of the semiconductor material. Also, a modified surface can include, for example, a textured surface.

As used herein, the term “textured surface” can refer to a surface having a topology with nanometer to micrometer-sized surface variations formed by irradiation with laser pulses.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of particles would either completely lack particles, or so nearly completely lack particles that the effect would be the same as if it completely lacked particles. In other words, a composition that is “substantially free of an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

The Disclosure

One shortcoming with current laser processing techniques and systems relates to the need to process multiple wafers simultaneously while maintaining substantial lasing uniformity from wafer to wafer. Furthermore, laser processing of a semiconductor wafer typically involves the exposure of one or more areas of the wafer surface to short pulse laser radiation, and in most cases the total area to be treated is significantly larger than the spot size of a single laser pulse. The traditional solution is to move the laser radiation across the surface of the wafer, where the wafer is maintained in a fixed position. In many instances, this is done using moveable mirrors. Due to the changing angle of the laser as it is redirected at subsequent portions of the wafer surface, the fluence of the laser radiation is varied as a function of wafer surface location. Lasing with such variation can result in a non-uniformly lased surface.

The present disclosure thus provides systems, materials, and methods for laser irradiating one or more semiconductor wafers while maintaining wafer to wafer lasing uniformity as well as lasing uniformity across a wafer surface. Furthermore, the present disclosure describes methods and systems that are configured to increase wafer throughput and increase accuracy with short pulse laser processing.

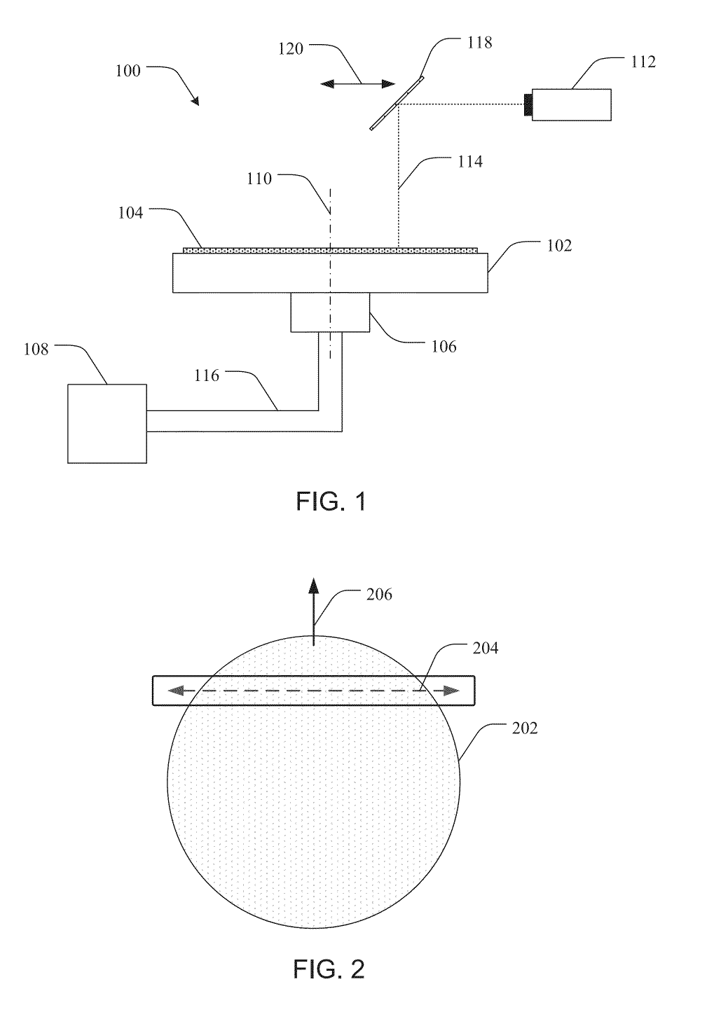

FIG. 1, for example, shows a system 100 for uniformly laser irradiating at least one wafer. Such a system can include a wafer platter 102 that is operable to receive and support a one or more wafers 104, and a rotational movement system 106 coupled to the wafer platter 102. The rotational movement system 106 is operable to rotate the wafer platter 102 in at least one of a clockwise or a counter clockwise direction. 110 represents a center axis around which the wafer platter 102 can be rotated. The system 100 can also include a linear movement system 108 coupled to the wafer platter 102. The linear movement system 108 is operable to move the wafer platter 102 along one or more linear axes. A linear movement coupling 116 can be coupled from the linear movement system 108 to the wafer platter 102 in order to translate the movements generated in the linear movement system 108 to the wafer platter 102. The linear movement system 108 may or may not be coupled to the wafer platter 102 via the rotational movement system 106. Furthermore, the system 100 can also include a laser source 112 oriented to deliver laser radiation 114 onto a wafer 104 supported by the wafer platter 102 at a fixed angle relative to the surface of the wafer 104. In some aspects, one or more mirrors 118 can be utilized to position the laser radiation 114 on the wafer 104 at the fixed angle. In some aspects, the rotational movement system 106 and the linear movement system 108 are operable to maintain the fixed angle across the entirety of the wafer surface. Additionally, in some aspects the mirror 118 can be moved (e.g. in the direction shown at 120) in order to move the laser radiation 114 across the surface of the wafer 104. In one aspect, the mirror 118 is moved in a direction and/or manner that maintains the fixed angle of the laser radiation 114 relative to the surface of the wafer 104. As one example, the mirror 118 can be moved in a direction that is along the axis of the incident (with respect to the mirror) laser radiation 114 such that the fixed angle does not substantially change as the laser radiation moves across the surface of the wafer. Additionally, it is also contemplated that a combination of two or more of rotational movement, linear movement, or mirror movement is operable to move the laser radiation across at least substantially all of the wafer surface without significantly changing the fixed angle. It also should be noted that, in some aspects, the system may not include a mirror and the laser source can be positioned to deliver laser radiation directly to the wafer surface.

The wafer platter can include any design and/or material capable of receiving and supporting a wafer for a laser processing procedure. For example, the wafer platter can be of any size shape that is beneficial to such lasing process. In some cases, the wafer platter can be size to match the approximate size of the wafer being processed. In other cases, the wafer platter can be sized to be smaller or larger than the wafer being supported. The wafer platter can also be of any appropriate shape. Non-limiting examples of such shapes can include circles, squares, rectangles, polygons, and the like. The surface of the wafer platter and receives the wafer can also have a variety of structural designs. For example, in one aspect the surface of the wafer platter can be smooth surface. In other aspects, the surface can be a rough surface such as a corrugated or other multi-elevational structure. In some aspects, the wafer platter can include a cutout region to facilitate placing and removing a wafer. In other aspects, wafer can be placed upon a wafer platter that is designed to allow the wafer to cantilever over at least one edge of the wafer platter.

The wafer platter can be made with a variety materials, and any material or combination of materials suitable to receive and support a wafer are considered to be within the present scope. Additionally, in some aspects materials can be selected to provide a beneficial interaction with the laser radiation. Non-limiting examples of suitable wafer platter material can include metals, metal alloys, ceramics, polymers, glass, quartz, and the like, including combinations thereof. In some cases, for example, the wafer platter material can include composite materials or combinations of materials. In one non-limiting example, the wafer platter can include a solid support such as a metal material, having a quartz coating covering the area onto which the wafer is placed. In this case the quartz coating can be used as a shield to protect the metal support, as laser radiation hitting the quartz material is dispersed readily.

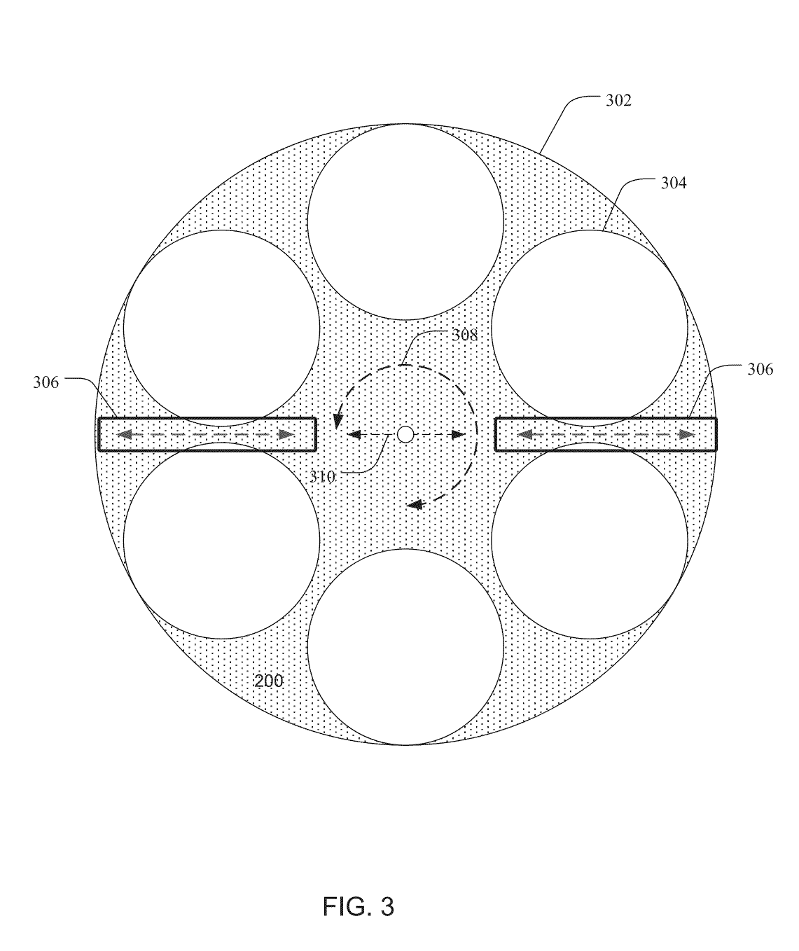

In some aspects, a single wafer platter designed to receive and support multiple wafers simultaneously. In such cases, the wafer platter can include multiple contact regions for placement of the plurality of wafers. In this manner, movement of the wafer platter can result in simultaneous movement of all associated wafers. One example of such a system is shown in FIG. 3, which is discussed more fully below. In other aspects, a system can include multiple wafer platters where each platter is operable to receive and support a single wafer. In one aspect, such a multiple platter system can include wafer platters that are operable to linearly move and/or rotate independently from one another. In another aspect, such a multiple platter system can include wafer platters that are operable to linearly move and/or rotate in a dependent fashion relative to one another.

It is noted, that while a wafer is shown and described in FIG. 1, such a wafer may or may not be considered to be included in the system as described. As such, in some aspects the wafer is not considered to be part of the scope of the system, but is merely being used to describe the operation system while in use. In other aspects, the wafer can be considered to be included in the scope of the system as described. Furthermore, while the term “wafer” is being used to describe the material being processed, it should be understood that any material capable of receiving laser processing is considered to be within the present scope. Non-limiting examples of such materials can include semiconductor wafers, metal surfaces, ceramics, and the like. Additionally, in some aspects the material being laser processed can be coupled to a device, such that the device rests upon the wafer platter. One example of such device can include a photo imager such as a CCD or CMOS device. Additionally, in one aspect the wafer can have a diameter that is equal to or greater than 200 mm.

As has been described, the system can include a linear movement system that is coupled to the wafer platter, either directly or indirectly, that is operable to move the wafer platter along one or more linear axes. In some aspects, the linear movement system is operable to move the wafer platter along at least two linear axes. In other aspects, the linear movement system is operable to move the wafer platter along at least three linear axes. As such, the wafer testing upon the wafer platter can be moved in any linear direction while the laser radiation remains at a fixed angle relative surface. As such, laser radiation can impinge on any region of the wafer surface without an angular change with respect to that surface that would cause variations in fluence as a function of wafer surface location.

The linear movement system can move the wafer platter in any linear direction, including in an x, y, or z direction relative to the surface of the wafer, or in any linear direction that is orthogonal thereto. Additionally, the linear movement system can move the wafer platter in a combination of directions using a step function such that the combination of movements causes the wafer platter to move in a nonlinear direction. Furthermore, in one aspect the linear movement system can be tilted in any direction out of the initial plane of the surface of the wafer. Such tilting can be accomplished by any technique structure known to those skilled in the art.

A rotational movement system is coupled to a wafer platter and is operable to rotate the wafer platter in a clockwise and/or a counter clockwise direction. In some cases, the rotational movement system can rotate the wafer platter back and forth in a clockwise and a counter clockwise direction. Depending on the nature wafer platter and the coupling on the rotational movement system, a given rotational movement system can rotate either a single wafer or multiple wafers. In one aspect, the rotational movement system can be integrated with at least a portion of the linear movement system. For example, the linear movement coupled that couples the linear movement system to the wafer platter can be configured to rotate. In another aspect, the rotational movement system can be separate from the linear movement system.

The nature of the rotation of the rotational movement system can vary depending on the design system. For example, one aspect the rotational movement system can rotate the wafer platter while one or more laser sources laser processes the entirety of the target region on a wafer. In another aspect, the rotational movement system can rotate the wafer platter while one or more laser sources laser processes multiple wafers simultaneously. As such, the speed of rotation can vary greatly depending on the design of the laser processing protocol. In one aspect, however, the wafer platter can be rotated with a speed of from about 0 Hz to about 600 Hz measured at the outside circumference of the wafer platter. In another aspect, the wafer platter can be rotated with a speed of from about 160 Hz to about 250 Hz measured at the outside circumference of the wafer platter. In yet another aspect, the wafer platter can be rotated with a speed of from about 0.1 Hz to about 10 Hz measured at the outside circumference of the wafer platter. It is noted that, for the purposes of the present disclosure, Hz is defined in rotations per second. As such, 10 Hz is equivalent to 10 rotations per second.

In one aspect of the present disclosure, a target region or regions of a wafer surface can be irradiated with short-pulse laser radiation. As such, a laser source can be included in the system and positioned to direct laser radiation having short pulse durations onto a wafer. The type of laser radiation used to surface modify a wafer material can vary depending on the material and the intended modification. Any laser radiation known in the art can be used with the systems and methods of the present disclosure. There are a number of laser characteristics that can affect the surface modification process and/or the resulting product including, but not limited to the wavelength of the laser radiation, pulse width, pulse fluence, pulse frequency, polarization, laser propagation direction relative to the wafer material, etc. In one aspect, a laser can be configured to provide pulsatile lasing of a semiconductor material. In one aspect such laser pulses can have a central wavelength in a range of about from about 10 nm to about 8 μm, and in other aspects from about 200 nm to about 1200 nm. The pulse width or pulse duration of the laser radiation can be in a range of about tens of femtoseconds to about hundreds of nanoseconds. While a variety of pulse durations contemplated, in one aspect the laser source is operable to emit laser radiation having short pulses of a duration of from about 10 femtoseconds to about 500 picoseconds. In another aspect, the laser source is operable to emit short pulses having a duration of from about 50 femtoseconds to about 200 picoseconds. In yet another aspect, the laser pulse durations can be in a range of from about 50 femtoseconds to about 50 picoseconds. In another aspect, the laser pulse durations can be from about 50 femtoseconds to about 500 femtoseconds. In another aspect, the laser pulse durations can be from about 1 picosecond to about 50 picoseconds.

The number of laser pulses irradiating the target region of the wafer can be from about 1 to about 2000. In one aspect, the number of laser pulses irradiating the target region can be from about 2 to about 1000. Further, the repetition rate or frequency of the pulses can be selected to be in a range of from about 10 Hz to about 10 μHz, or in a range of from about 1 kHz to about 1 MHz, or in a range from about 10 Hz to about 1 kHz. Moreover, the fluence of each laser pulse can be from about 1 kJ/m² to about 20 kJ/m², or from about 3 kJ/m² to about 8 kJ/m². The present disclosure can further include devices for monitoring the laser conditions in real-time. In other words, the system can monitor or measure the laser fluence, laser spot size, energy, etc. on the wafer surface during laser processing.

Furthermore, it is additionally contemplated that the present system can be utilized with the number of various laser sources of varying power and characteristics. As such, any laser source capable of laser processing the surface of a wafer is considered to be within the present scope. In one aspect, for example, the laser source is a short pulse laser source having an output power of greater than or equal to about 10 W. In another aspect, the laser source is a short pulse laser source having an output power of greater than or equal to about 20 W. In another aspect, the laser source is a short pulse laser source having an output power of greater than or equal to about 30 W. In yet another aspect, the laser source is a short pulse laser source having an output power of greater than or equal to about 40 W. In another aspect, the laser source is a short pulse laser source having an output power of greater than or equal to about 50 W. In a further aspect, the laser source is a short pulse laser source having an output power of greater than or equal to about 60 W. In a further aspect, the laser source is a short pulse laser source having an output power of greater than or equal to about 100 W. In a further aspect, the laser source is a short pulse laser source having an output power of greater than or equal to about 500 W.

A variety of semiconductor materials are contemplated for use with the surface modification processes of the present disclosure, all of which should be considered to be within the present scope. Examples of such semiconductor materials can include group IV materials, group II-VI materials, and group III-V materials from the periodic table. More specifically, exemplary group IV materials can include silicon, carbon (e.g. diamond), germanium, and combinations thereof. Various combinations of group IV materials can include silicon carbide and silicon germanium. It should be noted that amorphous moieties are also included in the group IV materials and those that follow. Exemplary amorphous materials include amorphous diamond and amorphous silicon. Exemplary group II-VI materials can include cadmium selenide (CdSe), cadmium sulfide (CdS), cadmium telluride (CdTe), zinc oxide (ZnO), zinc selenide (ZnSe), zinc sulfide (ZnS), zinc telluride (ZnTe), cadmium zinc telluride (CdZnTe, CZT), mercury cadmium telluride (HgCdTe), mercury zinc telluride (HgZnTe), and mercury zinc selenide (HgZnSe).

Exemplary group III-V materials can include aluminum antimonide (AlSb), aluminum arsenide (AlAs), aluminum nitride (AlN), aluminum phosphide (AlP), boron nitride (BN), boron phosphide (BP), boron arsenide (BAs), gallium antimonide (GaSb), gallium arsenide (GaAs), gallium nitride (GaN), gallium phosphide (GaP), indium antimonide (InSb), indium arsenide (InAs), indium nitride (InN), indium phosphide (InP), aluminum gallium arsenide (AlGaAs, AlxGal-xAs), indium gallium arsenide (InGaAs, InxGal-xAs), indium gallium phosphide (InGaP), aluminum indium arsenide (AlInAs), aluminum indium antimonide (AlInSb), gallium arsenide nitride (GaAsN), gallium arsenide phosphide (GaAsP), aluminum gallium nitride (AlGaN), aluminum gallium phosphide (AlGaP), indium gallium nitride (InGaN), indium arsenide antimonide (InAsSb), indium gallium antimonide (InGaSb), aluminum gallium indium phosphide (AlGaInP), aluminum gallium arsenide phosphide (AlGaAsP), indium gallium arsenide phosphide (InGaAsP), aluminum indium arsenide phosphide (AlInAsP), aluminum gallium arsenide nitride (AlGaAsN), indium gallium arsenide nitride (InGaAsN), indium aluminum arsenide nitride (InAlAsN), gallium arsenide antimonide nitride (GaAsSbN), gallium indium nitride arsenide antimonide (GaInNAsSb), gallium indium arsenide antimonide phosphide (GaInAsSbP); and combinations thereof.

In one aspect, the semiconductor material can be selected from the group consisting of silicon, carbon, germanium, aluminum nitride, gallium nitride, indium gallium arsenide, aluminum gallium arsenide, and combinations thereof. In yet another aspect, the semiconductor material can be silicon.

A variety of dopant materials are contemplated, and any such material that can be used to surface modify a semiconductor material according to the present invention should be considered to be within the present scope. It should be noted that the particular dopant utilized can vary depending on the semiconductor being surface modified, and the intended use of the resulting semiconductor material. Non-limiting examples can include, however, sulfur-containing fluids such as H₂S, SF₆, and SO₂; fluorine containing fluids such as ClF₃, PF₅, F₂ SF₆, BF₃, GeF₄, WF₆, SiF₄, HF, CF₄, CHF₃, CH₂F₂, CH₃F, C₂F₆, C₂HF₅, C₃F₈, C₄F₈, and NF₃; boron containing fluids such as B(CH₃)₃, BF₃, BCl₃, and B₂H₆; phosphorous containing fluids such as PF₅ and PH₃; chlorine containing fluids such as Cl₂, SiH₂Cl₂, HCl, SiCl₄; arsenic containing fluids such as AsH₃; antimony containing fluids; and mixtures and combinations thereof. In one aspect, the dopant fluid can have a density that is greater than air. The dopants can be incorporated into a fluid layer that is adjacent the semiconductor substrates. In another aspect, the dopant fluid can include H₂S, SF₆, Se, Te, or mixtures thereof. In a further aspect, the dopant fluid can be an electron donating element or a hole donating element. In yet another aspect, the dopant can be SF₆ and can have a predetermined concentration range of 5.0×10⁻⁸ mol/cm³-5.0×10⁻⁴ mol/cm³. In one aspect, for example, the inert fluid such as, but not limited to, nitrogen, argon, neon, helium, and the like can be used. The inert species can be incorporated into a fluid layer that is adjacent the semiconductor substrate. It should be noted that the term “inert” refers to a fluid layer that does not unduly interfere with the surface modification process, and does not necessarily mean that the fluid is inert with respect to all materials.

Is contemplated that the present scope includes any technique or design configuration that is capable of at least substantially maintaining laser fluence across the surface of the wafer. By maintaining laser fluence in such a manner, laser processing uniformity is maintained across both the surface of an individual wafer and across the surfaces between multiple wafers. As such, any technique that maintains laser fluence exposure history across the wafer surface to maintain laser processing uniformity is considered to be within the present scope. In one aspect, such a technique can include maintaining the laser radiation at a fixed angle with respect to the surface of the wafer and moving the wafer in a manner that maintains the fixed laser radiation angle. This can include maintaining the laser radiation beam at a fixed location in space and moving the wafer relative to the beam. In another aspect, the beam can be moved across the surface of a wafer and the wafer platter can be tilted to compensate for the change in the radiation beam angle, thus maintaining a fixed angle between the beam and the wafer surface. In another aspect, maintaining laser fluence exposure history can be accomplished by a combination of laser beam movement and the movement of the wafer platter, whether that be linear movement, rotational movement, or both.

As has been described, in some cases the laser radiation can be delivered in a beam at an angle that is fixed relative to the wafer surface. In one aspect, this fixed angle can be normal or at least substantially normal to the wafer surface. As such, as the linear movement system and/or the rotational movement system moves the wafer, the angle between the laser radiation beam and the wafer surface can remain fixed at all points across the wafer surface, thus maintaining fluence exposure history. In another aspect, the laser radiation beam can be delivered to the wafer surface at a fixed obtuse or a fixed acute angle relative to the wafer surface. Even at such non-perpendicular angles, fluence exposure history can be maintained across the entire surface due to the fixed angle. In general, the beam can be incident on the wafer surface at any incident angle. As one example, the laser beam can be incident at any angle from about −85° to about 85°, and more specifically between about —45° to about 45°.

In yet another aspect, the beam can be delivered at an angle related to the Brewster's angle of the wafer material. For example, in one aspect the fixed angle can be within about ±15° of the Brewster's angle for the wafer material. In another aspect, the fixed angle can be within about ±5° of the Brewster's angle for the wafer material. In yet another aspect, the fixed angle can be substantially at the Brewster's angle for the wafer material.

FIG. 2, for example, illustrates a wafer 202 that can be linearly translated in one direction as is shown at 206, and a laser beam rastering back and forth within the laser pathway shown at 204. The combination of such rastering along with the linear translation 206 of the wafer 202 causes the laser pathway to cover the entire surface of the wafer 202. The back-and-forth motion of the laser beam within the laser pathway 204 can be accomplished with the laser beam at a fixed angle relative to the surface of the wafer 202, thus maintaining laser fluence at each point along the path. Because the laser radiation is delivered in short pulse durations, the laser beam is moved as step function across the wafer 202. In one aspect, the laser beam can be moved by devices such as galvo mirrors or an otherwise linearly moving mirror to provide linear scanning motion, similar to what is shown in FIG. 1. In some cases, it may be beneficial to tilt the underlying wafer platter in order to maintain a fixed angle of the laser beam relative to the wafer surface as beam moves across the surface. In such cases, even laser coverage can be achieved by adjusting scanning speeds in the directions of the moving wafer and the moving laser beam to appropriately provide even laser fluence across the entire processed surface area. The scanning speed in each direction can depend on the laser energy, beam spot size, and the repetition rate (or pulse energy). In one aspect, the beam can be delivered using a round beam. The moving laser beam allows for fast scanning speeds. In one aspect, the linear scanning movement of the laser beam can be from about 50 mm/s to about 10 m/s. In addition to the linear movement system, the wafer can also be moved by a conveyor belt or other process tool.

In one aspect, as is shown in FIG. 3, a wafer platter 302 is shown supporting a plurality of wafers 304. Multiple target regions 306 are shown at which laser radiation is translated back-and-forth across the wafers to perform laser processing. In those aspects employing a cover between the wafers in the laser sources, apertures can be formed in the cover to allow the passage of laser radiation at the multiple target regions 306. The wafer platter 302 can be rotated in either a clockwise or a counter clockwise direction 308 such that the laser beam scan is normal to or at a fixed angle to the linear velocity vector of any point on the surfaces of the rotating wafers. The angular velocity of the wafer platter rotation can be controlled using electronics to allow the repetition rate of the fixed angle laser beam and the laser pulse exposure overlap to be constant for a given power and fluence of the laser beam, which are optimized to meet the optimum process conditions. The combination of the wafer platter rotational motion with the laser beam's linear scan from one edge of the wafer to the other (outer to inner or inner to outer) along the direction at a fixed angle to the axis of rotation results in a uniform spiral laser beam exposure pattern over the entire process area of the wafer platter. This uniform laser beam pattern maintains the fluence exposure history at each point across the surface of each wafer. The parameters of the spiral beam pattern are directly a function of both the angular rotational velocity of the wafer platter and the linear scan velocity of the beam. The present disclosure is compatible with both substantially round beam profiles, as well as elongated line beams. This can include Gaussian beam profiles, top-hat beam profiles, or any other manner of beam profile that can be created. Additionally, in some aspects the wafer platter 302 can be translated in a linear direction back-and-forth as is shown at 310. In this manner, the laser beam can remain at a fixed angle and a fixed position while the wafer platter 302 is translated back-and-forth beneath the beam. In other aspects, the beam itself can be translated back-and-forth through the target regions 306. The store combination of translation, by whatever technique utilized, and rotation of the wafer platter 302 a uniform laser processed surface can be achieved. It is noted that, in some aspects, a single target region 306 is contemplated. In other aspects, multiple target regions of two or more are contemplated. Additionally, the arrows within the target regions 306 shown in FIG. 3 represent the movement or scanning direction of the laser radiation.

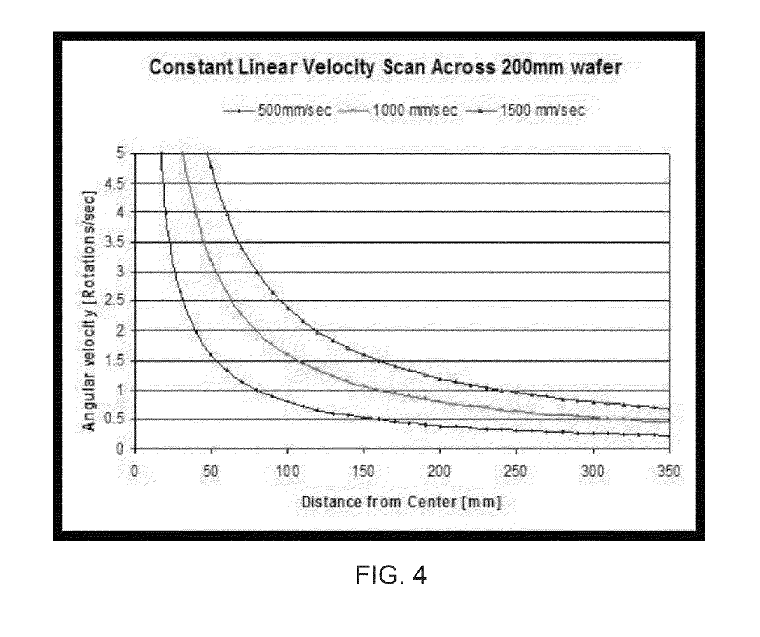

The degree of laser pulse overlap along the spiral for a given pulse repetition rate is a function of the linear velocity of the impact point on the wafer surface moving perpendicularly to the axis of rotation. For a given velocity w of the wafer platter the linear velocity v of any point exposed to the laser pulse changes as a function of distance r from the axis of rotation according to the formula v=ωr. Thus, in order to maintain a constant linear velocity v as a function of the radius and the resulting constant pulse overlap in the rotation (spiral), the angular velocity of the wafer platter should be varied by a factor of Rₘₐₓ/r, in which Rₘₐₓ is the radial distance of the most outer processing point from the axis of rotation and r is the corresponding pulse impact radius in relation to the action of rotation. As the laser beam is scanned linearly from the outer edge of the rotating wafers to their most inner edge the wafer platter angular rotation is accelerated according to the above formula (see FIG. 4), thus retaining the constant linear velocity along the spiral line “drawn” by the laser beam on the wafer platter. Similarly, for a given pulse repetition rate, the degree of laser pulse overlap between the two adjacent spiral lines along the radius of the wafer platter is a function of both the angular velocity of the rotation and the velocity of the laser beam scan along the radius. The velocity of the laser beam scan along the radius is set proportionally to the changes in the angular velocity of the rotation such that the ratio of the two velocities remains constant during the scan of the entire process area from the outer edge to the inner edge of the wafer surface.

As has been described, in some aspects a system can comprise a single laser source delivering a single laser beam to the wafer platter. In other aspects, multiple laser sources can be included in the system. Such laser sources can be utilized for processing one or more wafers. In some cases for example, multiple lasers can be utilized to process a single wafer. In other aspects, multiple lasers can be utilized to laser process multiple wafers, where each laser processes the entire target region of a single wafer. In yet other aspects, multiple lasers can be utilized to collectively process multiple wafers. Such “wafer sharing” can be utilized to generate a uniformly processed surface by using each of the multiple lasers to provide laser radiation to distinct portions of the target region.

In some aspects, the system can further include a housing configured to at least partially enclose the wafer platter. In some aspects, the housing is an open and thus does not fully enclose the wafer platter from the room environment, while in other aspects the housing is a closed housing that effectively seals the wafer platter from contact with the room atmosphere. In cases where the housing is a closed housing, a lid or other access feature can be associated with housing to provide access to the wafer platter. Additionally, it may be beneficial for apertures to be formed in the housing to facilitate the transmission a laser radiation to the wafer is contained inside.

In one aspect, wafers can be manually loaded onto the wafer platter or wafer platters located within the housing. In other aspects, automatic loading of wafers can be accomplished using robotic arm, conveyor belt, or other wafer movement system that allows transport of one or more wafers into the housing. Depending on the design of the system and the wafer loading method available, the housing can be opened, the wafer platter can be loaded with one or more wafers, the housing can be closed if it is a closed housing system, and the proper environment can be introduced therein. It is additionally contemplated, that the housing can include an input chamber capable of placing a wafer therein and equilibrating the conditions in the input chamber with the conditions in the housing. The wafer can then be drawn onto the wafer platter without the need for purging the internal environment and opening the housing. A similar output chamber can be utilized whereby a processed wafer is removed from the wafer support and transported therein. The output chamber can be purged and equilibrated to room atmosphere conditions, and the process wafer can be removed without the need of opening the housing.

In another aspect, the housing can include a fluid input system coupled to the housing and operable to deliver a fluid therein. In this manner, inert gases, dopants, or other components of the processing environment can be introduced into the housing. In another aspect, the housing can include a fluid output system coupled to the housing and operable to remove a fluid therefrom. Such a fluid output system can remove spent fluids, contaminants, and debris resulting from the laser process.

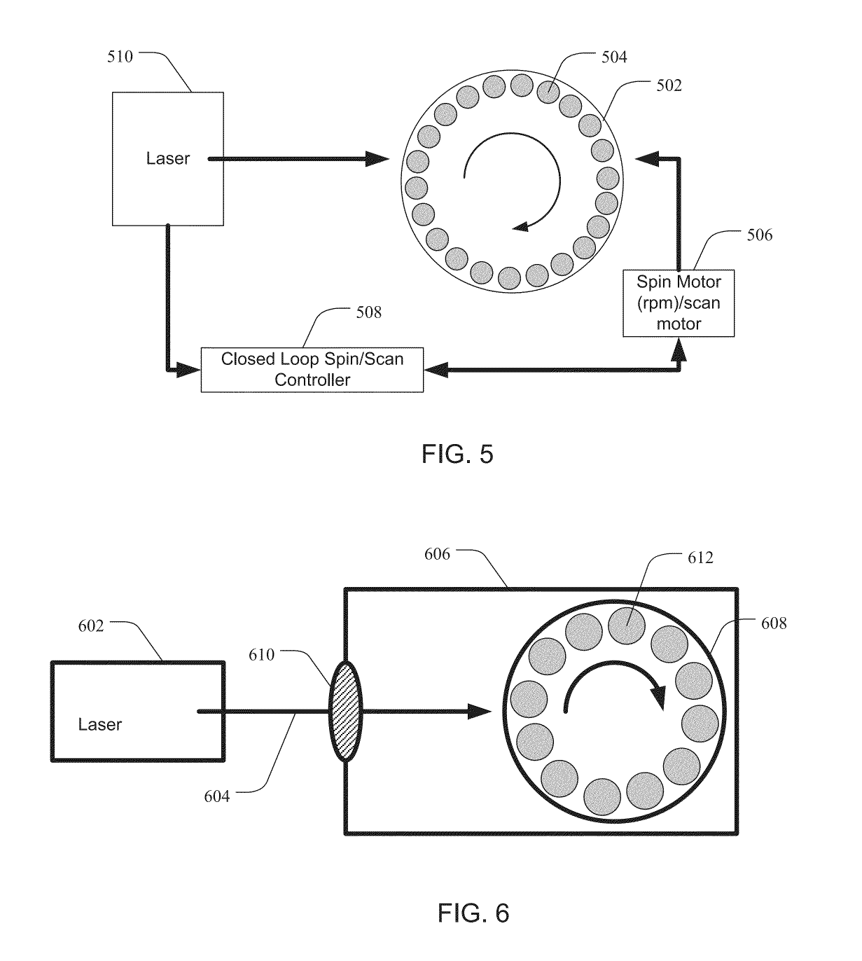

As is shown in FIG. 5, the present disclosure additionally provides a laser system having a wafer platter 502 for supporting multiple wafers 504, a spin motor 506 for rotating the wafer platter 502, a closed loop spin/scan controller 508 and a laser source 510 for irradiating the surface of the wafers 504. As such, a wafer is moving effectively in a linear direction while the laser beam is scanning along the radius of the wafer platter 502. Additionally, in some aspects the spot size of the laser radiation can be increased to process more surface area. However, he can be beneficial to optimize the spot size and power distribution over the target region.

Turning to FIG. 6, a system is shown having a laser 602 operable to emit a laser radiation beam 604, an enclosure 606 for housing a wafer platter 608, a cover having a quartz medium and/or window 610 attached to the enclosure 606. The enclosure 606 can provide a controlled gas/vacuum environment conducive for laser processing wafers 612. The wafer platter 608 can rotate in either a clockwise or counter-clockwise direction. The wafer platter 608 can also be attached to a linear movement system that can move the wafer platter in at least one linear direction, thus allowing the laser beam 604 to be in a fixed or stationary position, while uniformly lasing at least a portion of the wafer surface area. The resultant wafers can have surface features or textures formed thereon and can have increased absorption or enhanced quantum efficiencies for electromagnetic radiation having at least one wavelength in the range of about 700 nm to about 1200 nm, as compared to non-lased semiconductor substrates.

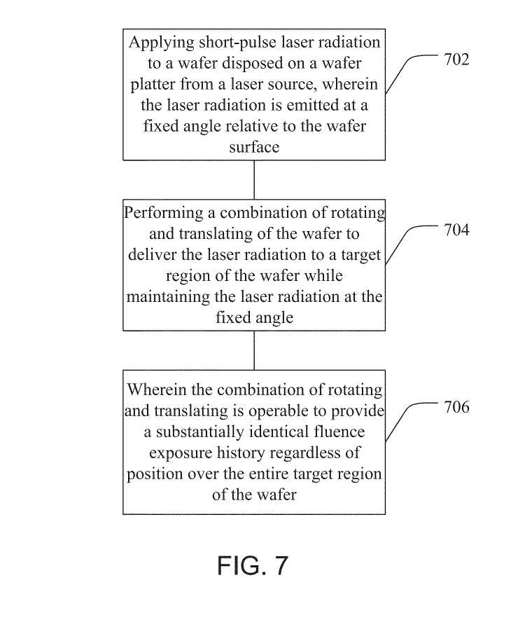

The present disclosure additionally provides various methods associated with laser processing. In one aspect as is shown in FIG. 7, for example, method of uniformly lasing at least one wafer is provided. Such a method can include 702 applying short-pulse laser radiation to a wafer disposed on a wafer platter from a laser source, wherein the laser radiation is emitted at a fixed angle relative to the wafer surface, and 704 performing a combination of rotating and translating of the wafer to deliver the laser radiation to a target region of the wafer while maintaining the laser radiation at the fixed angle, 706 wherein the combination of rotating and translating is operable to provide a substantially identical fluence exposure history regardless of position over the entire target region of the wafer. In one aspect, the target region can be substantially all of the wafer surface. In another aspect, the combination of rotating and translating is operable to maintain a substantially identical fluence exposure history where the laser radiation contacts the wafer at an edge region of the wafer as compared to a center region of the wafer. In yet another aspect, the fixed angle is substantially normal to the surface of the wafer.

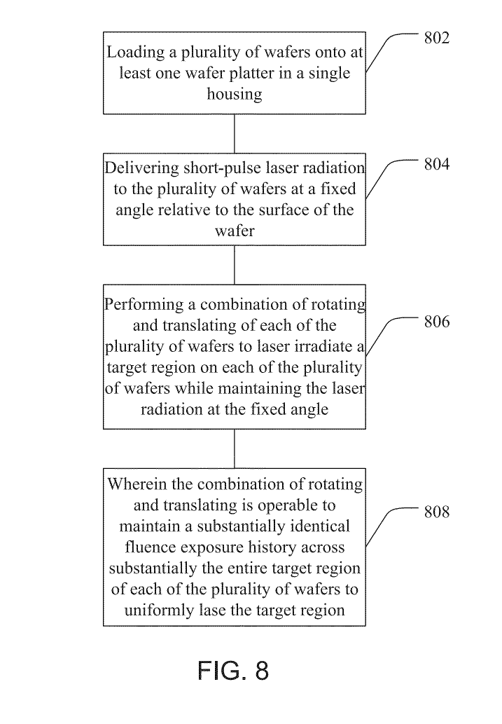

In yet another aspect, as is shown in FIG. 8, a method of uniformly lasing a plurality of wafers in a single batch process is provided. Such a method can include 802 loading a plurality of wafers onto at least one wafer platter in a single housing, 804 delivering short-pulse laser radiation to the plurality of wafers at a fixed angle relative to the surface of the wafer, and 806 performing a combination of rotating and translating of each of the plurality of wafers to laser irradiate a target region on each of the plurality of wafers while maintaining the laser radiation at the fixed angle, 808 wherein the combination of rotating and translating is operable to maintain a substantially identical fluence exposure history across substantially the entire target region of each of the plurality of wafers to uniformly lase the target region. In another aspect, the fixed angle is substantially normal to the surface of the wafer. In yet another aspect, the target region is substantially all of the wafer surface. In a further aspect, delivering short-pulse laser radiation further includes delivering short-pulse laser radiation from a plurality of laser sources. In yet a further aspect, delivering short-pulse laser radiation from a plurality of laser sources further includes delivering short-pulse laser radiation to at least a portion of the plurality of wafers simultaneously. In another aspect, the short-pulse laser radiation has a laser pulse duration of from about 10 femtoseconds to about 500 picoseconds.

Of course, it is to be understood that the above-described arrangements are only illustrative of the application of the principles of the present disclosure. Numerous modifications and alternative arrangements may be devised by those skilled in the art without departing from the spirit and scope of the present disclosure is intended to cover such modifications and arrangements. Thus, while the present disclosure has been described above with particularity and detail in connection with what is presently deemed to be the most practical embodiments of the disclosure, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. A system for uniformly laser irradiating at least one wafer, comprising:
a wafer platter operable to receive and support one or more wafers;
a rotational movement system coupled to the wafer platter, the rotational movement system operable to rotate the wafer platter in at least one of a clockwise or a counter clockwise direction;
a linear movement system coupled to the wafer platter and operable to move the wafer platter along one or more linear axes; and
a laser source oriented to deliver laser radiation onto a wafer supported by the wafer platter at a fixed angle relative to the surface of the wafer, the rotational movement system and the linear movement system operable to maintain the fixed angle across the entirety of the wafer surface.

2. The system of claim 1, further comprising a housing configured to at least partially enclose the wafer platter.

3. The system of claim 2, further comprising a fluid input system coupled to the housing and operable to deliver a fluid therein.

4. The system of claim 2, further comprising a fluid output system coupled to the housing and operable to remove a fluid therefrom.

5. The system of claim 1, wherein the linear movement system is operable to move the wafer platter along at least two linear axes.

6. The system of claim 1, wherein the linear movement system is operable to move the wafer platter along at least three linear axes.

7. The system of claim 1, wherein the fixed angle is substantially normal to the surface of the wafer.

8. The system of claim 1, wherein the fixed angle is within about ±15° of the Brewster's angle for the wafer material.

9. The system of claim 1, further comprising multiple wafer platters for processing multiple wafers.

10. The system of claim 1, further comprising multiple laser sources for processing one or more wafers.

11. The system of claim 1, wherein the laser source is a short pulse laser source having an output power of greater than 10 W.

12. The system of claim 1, wherein the laser source is a short pulse laser source having an output power of greater than 30 W.

13. The system of claim 1, wherein the laser source is operable to emit short pulses having a duration of from about 10 femtoseconds to about 500 picoseconds.

14. A method of uniformly lasing at least one wafer, comprising:
applying short-pulse laser radiation to a wafer disposed on a wafer platter from a laser source, wherein the laser radiation is emitted at a fixed angle relative to the wafer surface;
performing a combination of rotating and translating of the wafer to deliver the laser radiation to a target region of the wafer while maintaining the laser radiation at the fixed angle, wherein the combination of rotating and translating is operable to provide a substantially identical fluence exposure history regardless of position over the entire target region of the wafer.

15. The method of claim 14, wherein the target region is substantially all of the wafer surface.

16. The method of claim 14, wherein the combination of rotating and translating is operable to maintain a substantially identical fluence exposure history where the laser radiation contacts the wafer at an edge region of the wafer as compared to a center region of the wafer.

17. The method of claim 14, wherein the fixed angle is substantially normal to the surface of the wafer.

18. A method of uniformly lasing a plurality of wafers in a single batch process, comprising:
loading a plurality of wafers onto at least one wafer platter in a single housing;
delivering short-pulse laser radiation to the plurality of wafers at a fixed angle relative to the surface of the wafer; and
performing a combination of rotating and translating of each of the plurality of wafers to laser irradiate a target region on each of the plurality of wafers while maintaining the laser radiation at the fixed angle, wherein the combination of rotating and translating is operable to maintain a substantially identical fluence exposure history across substantially the entire target region of each of the plurality of wafers to uniformly lase the target region.

19. The method of claim 18, wherein the fixed angle is substantially normal to the surface of the wafer.

20. The method of claim 18, wherein the target region is substantially all of the wafer surface.

21. The method of claim 20, wherein delivering short-pulse laser radiation further includes delivering short-pulse laser radiation from a plurality of laser sources.

22. The method of claim 21, wherein delivering short-pulse laser radiation from a plurality of laser sources further includes delivering short-pulse laser radiation to at least a portion of the plurality of wafers simultaneously.

23. The method of claim 18, wherein the short-pulse laser radiation has a laser pulse duration of from about 10 femtoseconds to about 500 picoseconds.
